(19) United States
(12) Patent Application Publication
(10) Pub. No.: US 2024/0072059 A1
(43) Pub. Date: Feb. 29, 2024

(54) FDSOI DEVICE INCLUDING SELF-ALIGNED DIFFUSION BREAK

(71) Applicant: Applied Materials, Inc., Santa Clara, CA (US)

(72) Inventors: Sipeng Gu, Clifton Park, NY (US); Qintao Zhang, Mt Kisco, NY (US)

(73) Assignee: Applied Materials, Inc., Santa Clara, CA (US)

(21) Appl. No.: 17/900,386

(22) Filed: Aug. 31, 2022

(51) Int. Cl. H01L 27/12; H01L 21/84; H01L 29/06; H01L 29/40; H01L 29/417; H01L 29/66

(52) U.S. Cl. CPC H01L 27/1203; H01L 21/84; H01L 29/0649; H01L 29/401; H01L 29/41783; H01L 29/66545

(57) ABSTRACT

Disclosed herein are approaches for forming a FDSOI, single diffusion break device. In one approach, a method may include providing a plurality of gates in a stack of layers, wherein each gate of the plurality of gates comprises a sidewall spacer, and forming a mask over the stack of layers, wherein an opening through the mask exposes a dummy gate of the plurality of gates. The method may further comprise etching a gate material of the dummy gate to form a recess in a silicon-on-insulator (SOI) layer of the stack of layers, implanting oxygen ions into the recess, and annealing the SOI layer within the recess to form an isolation area.

### FIELD OF THE DISCLOSURE

The present disclosure relates to semiconductor structures and, more particularly, to a fully depleted silicon on insulator (FDSOI), single diffusion break device and methods of formation.

### BACKGROUND OF THE DISCLOSURE

In CMOS (complementary metal oxide semiconductor) devices, a large number of P-type and N-type transistor elements may be integrated into a single semiconductor chip and may be functionally connected so as to form highly complex functional units, such as complex control circuitry, microcontrollers, CPUs (central processing units) and the like.

Significant advances in terms of superior performance and increased integration density may be associated with the continuing reduction of critical dimensions of transistor elements. The capability of reliably producing reduced critical dimensions in every new device generation has been mainly driven by significant improvements in lithography techniques and correlated patterning strategies, wherein even critical dimensions well beyond the optical resolution capabilities of modern lithography equipment may be obtained. For example, defining active regions for transistor elements requires sophisticated lithography and patterning strategies, wherein two independent patterning sequences are involved, thereby contributing to overall cost and complexity of the manufacturing process.

Current art designs provide electrostatic isolation using dummy gates between active devices of a silicon-on-insulator (SOI) structure. However, this generally increases overall leakage. In another current art design, an insulating material is used as a filler after etching the SOI. However, this approach demonstrates channel uni-axial strain loss, which causes device degradation. It is with respect to these and other drawbacks of the current art that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a plurality of gates in a stack of layers, wherein each gate of the plurality of gates includes a sidewall spacer, and forming a mask over the stack of layers, wherein an opening through the mask exposes a dummy gate of the plurality of gates. The method may further include removing a gate material of the dummy gate to form a recess, wherein the recess exposes a silicon-on-insulator (SOI) layer of the stack of layers, implanting oxygen ions into the recess, and annealing the SOI layer within the recess to form an isolation area.

In another aspect, a method may include forming an isolation area in a silicon-on-insulator (SOI) device, the method including forming a plurality of gates in a stack of layers, wherein each gate of the plurality of gates includes a sidewall spacer along a gate material. The method may further include forming a mask over the stack of layers, wherein an opening through the mask exposes a dummy gate of the plurality of gates, etching the gate material of the dummy gate to form a recess in a SOI layer of the stack of layers, implanting oxygen ions into a bottom surface of the recess, and annealing the bottom surface of the recess to form an isolation area in the SOI layer.

In yet another aspect, a method may include forming a fully depleted silicon-on-insulator (FDSOI) device having a diffusion break, wherein the method includes forming a plurality of gates in a stack of layers, and wherein each gate of the plurality of gates includes a sidewall spacer along a gate material. The method may further include forming a mask over the stack of layers, wherein an opening through the mask exposes a dummy gate of the plurality of gates, and forming the diffusion break by etching the gate material of the dummy gate to form a recess in a SOI layer of the stack of layers, implanting oxygen ions into a bottom surface of the recess to form an isolation area in the SOI layer, and forming a fill material within the recess, wherein the fill material is formed atop the isolation area.

### BRIEF DESCRIPTION OF THE DRAWINGS

The accompanying drawings illustrate exemplary approaches of the disclosure, including the practical application of the principles thereof, as follows:

FIG. 1 is a cross-sectional side view of layers of a device, according to embodiments of the present disclosure;

FIG. 2 is a side cross-sectional view illustrating the device following formation of an opening above a dummy gate, according to embodiments of the present disclosure;

FIG. 3 is a side cross-sectional view illustrating the device after removal of a gate material from the dummy gate, according to embodiments of the present disclosure;

FIG. 4 is a side cross-sectional view illustrating the device during an oxygen ion implant and optional annealing process, according to embodiments of the present disclosure;

FIG. 5 is a side cross-sectional view illustrating formation of a fill material within the opening to form a diffusion break in the device, according to embodiments of the present disclosure;

FIG. 6 is a side cross-sectional view of a portion of a FDSOI device, according to embodiments of the present disclosure; and

FIG. 7 illustrates a schematic diagram of a processing apparatus according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

To address the deficiencies of the prior art described above, embodiments of the present disclosure advantageously provide a fully depleted silicon on insulator (FD-SOI) device formed in part using an oxygen ion implantation process for local oxide isolation within a self-aligned dummy gate. The oxidized isolation area provides a physical isolation between source and drain regions of adjacent gate structures. This physical isolation or break of the substrate material advantageously reduces leakage of the gate devices while also increasing device performance, thus allowing different voltage controls for the source/drain regions and active gate structures and reducing the overall footprint of the structure.

In some embodiments, to enable future device scaling, the oxygen ion implant is part of a self-aligned diffusion break formation process, which results in a well-defined diffusion break size not dependent solely upon lithography. In some embodiments, the oxide isolation formation is formed at a low temperature, and after formation of a plurality of gates and source/drain (S/D) regions in the device. An optional laser anneal process may then be performed.

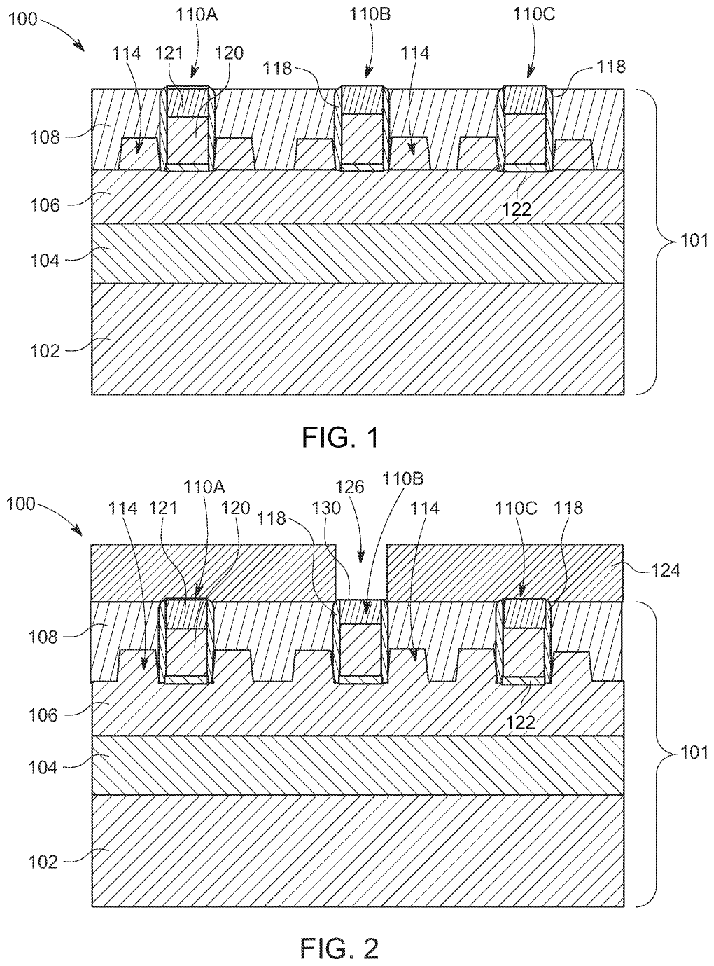

FIG. 1 is a side cross-sectional view of a portion of semiconductor device (hereinafter “device”) 100, such as a fully depleted silicon on insulator (FD-SOI) device, according to one or more embodiments. As shown, the device 100 may include a stack of layers 101 including, but not limited to, a silicon substrate 102, a buried oxide (BOX) layer 104 formed atop the silicon substrate 102, a SOI layer 106 formed over the BOX layer 104, and a silicon dioxide (SiO₂) layer 108 formed over the SOI layer 106. In various embodiments, the SOI layer 106 may include a semiconductor material such as, e.g., C-SiGe for a PFET device or fully depleted silicon (at least in the channel region) for an NFET device.

The device 100 may further include a plurality of gates 110A-110C formed therein, at least one of which (e.g., 110B) is a dummy gate. Gates 110A and 110C may be active gates. Although non-limiting, the gates 110A-110C may include a gate material 120 and a capping material 121, e.g., nitride, over the gate material 120. In some embodiments, each of the gates 110A-110C may include a stopping layer 122.

The device 100 may further include S/D regions 114 formed along opposite sides of each of the gates 110A-110C. In some embodiments, the S/D regions 114 may be grown from an epitaxial material, such as a Si or SiGe material. The S/D regions 114 may also include a silicon capping material in some examples.

As further shown, each of the gates 110A-110C includes a sidewall spacer 118 between the gate material 120 and the S/D regions 114. The sidewall spacers 118 may be formed on sides of the gates 110A-110C using conventional deposition processes followed by an anisotropic etching process. In some embodiments, the sidewall spacers 118 may be a nitride material or other low-k dielectric material. For example, the sidewall spacers 118 may be SiBCN. Embodiments herein are not limited in this context, however.

Next, as shown in FIG. 2, a mask 124 may be formed over the stack of layers 101 and over the gates 110A-110C, and an opening 126 may be formed (e.g., etched) through the mask 124 to expose the dummy gate 110B. In some embodiments, the opening 126 may have a width extending between each of the spacers 118. Although non-limiting, the opening 126 may be formed by placing a resist over a material of the mask 124 and exposing it to energy (e.g., light) to form a pattern (e.g., the opening 126). An etching process with a selective chemistry, e.g., reactive ion etching (RIE), may be used to form the opening 126 in the material of the mask 124 through the opening of the resist.

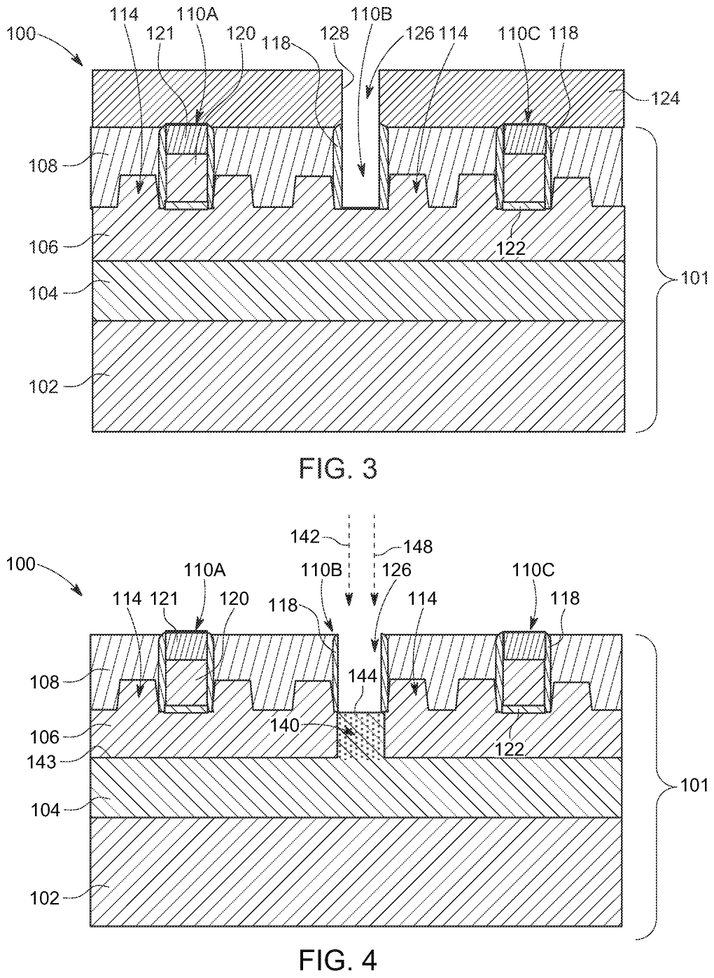

The opening 126 may initially be recessed to a top surface 130 of the dummy gate 110B, as shown in FIG. 2. The opening 126 may then be further recessed into the stack of layers 101, as shown in FIG. 3, e.g., by removing the capping material 121, the gate material 120, and the stopping layer 122 of the dummy gate 110B. In some embodiments, the opening 126 may extend to the SOI layer 106. In some embodiments, the SOI layer 106 may act as an etch stop layer. As shown, no sacrificial spacer or insulator material is present along the sidewalls 128 defining the opening 126 of the mask 124 during the etching process. Instead, the etching process is self-aligned (e.g., dry or wet), using the sidewall spacer 118 as a lateral stopping layer. As a result, an extra step from conventional processing can be removed, thus improving throughput and reducing cost.

As shown in FIG. 4, the mask 124 may be removed, and an isolation area 140 may be formed in the SOI layer 106, beneath the dummy gate 110B. In other embodiments, the mask 124 may remain in place while the isolation area 140 is formed. As shown, the isolation area 140 may generally extend to an upper surface 143 of the BOX layer 104. In some embodiments, the isolation area 140 may be formed by an oxygen ion implant 142 into a bottom surface 144 of the opening 126. The oxygen ion implant 142 may be a high-current plasma oxygen implant performed at a low temperature, e.g., below 400° C. More specifically, the oxygen ion implant 142 is performed at room temperature (e.g., between 15 and 30° C.) to prevent causing any dopant change during the implant. In one non-limiting example, an ion implant energy of the oxygen ion implant 142 may be approximately 3 Key, and a dose of the oxygen ion implant 142 may be approximately 1E15 to 1E17 atom/cm² to achieve fully oxidation. Embodiments herein are not limited in this context, however.

In some embodiments, the isolation area 140 may be further formed by performing an anneal 148 through the opening 126 and into the bottom surface 144. Although non-limiting, the anneal 148 may be a laser anneal. More specifically, the anneal 148 may be a MOL silicide laser anneal. Due to the previous oxygen ion implant 142, no high temperature anneal is needed to oxidate the exposed surfaces of the opening 126. The sidewall spacer 118 continues to act as a lateral stopping layer during the anneal 148. It will be appreciated that one or more implant/anneal cycles may be performed to create the isolation area 140 within the SOI layer 106. As shown, a width of the isolation area 140 is generally defined by the sidewall spacer 118. Once formed, the isolation area 140 provides dielectric isolation to enable continuous active channels on the FDSOI device 100.

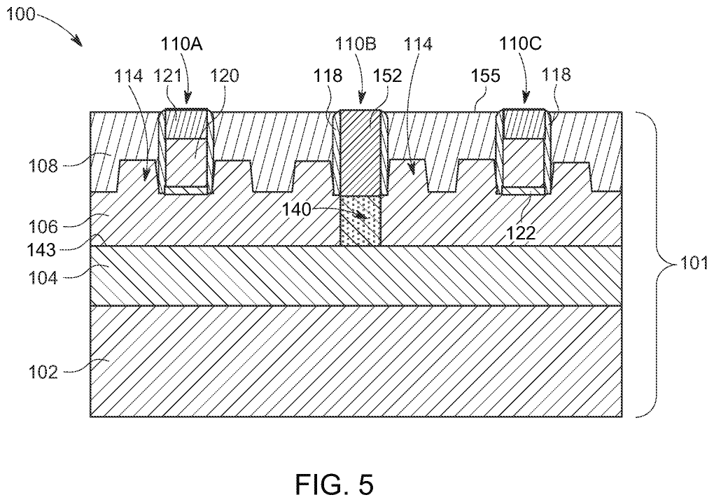

A fill material 152 may then be deposited within the opening 126, as shown in FIG. 5. In some embodiments, the fill material 152 may be a nitride, which is deposited over the device 100 and then removed (e.g., planarized) from an upper surface 155 of the silicon dioxide layer 108. As shown, the fill material 152 may be deposited directly atop the isolation area 140. Once deposited, the fill material 152, the isolation area 140, and the sidewall spacer 118 act as a diffusion break for the device 100.

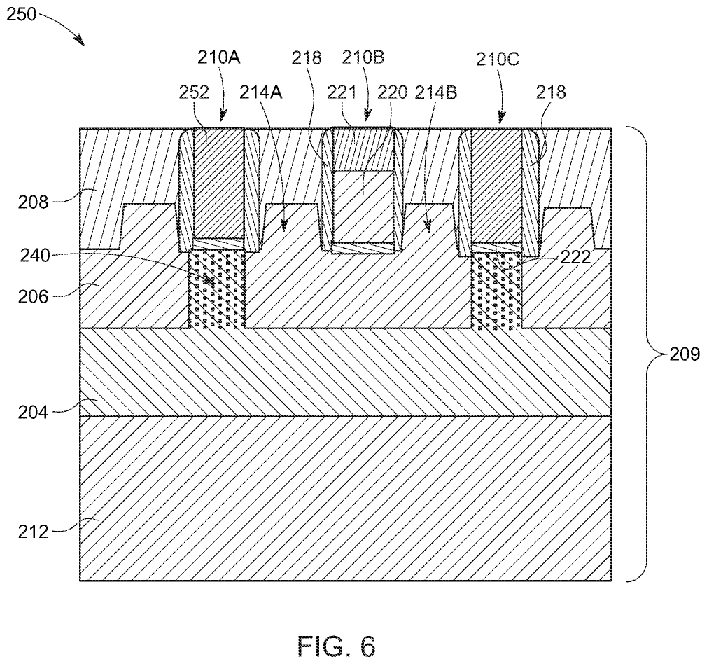

FIG. 6 is a side cross-sectional view of a portion of another semiconductor device (hereinafter “device”) 250, such as a fully depleted silicon on insulator (FD-SOI) device, according to another embodiment. The device 250 may be the same or similar in many aspects to the device 100 described above. As such, only certain aspects of the device 250 will hereinafter be described for the sake of brevity. As shown, the device 250 may include a stack of layers 209 including, but not limited to, a silicon substrate 212, a buried oxide (BOX) layer 204 formed atop the silicon substrate 212, a SOI layer 206 formed over the BOX layer 204, and a silicon dioxide (SiO₂) layer 208 formed over the SOI layer 206.

The device 250 may further include a plurality of gates 210A-210C formed in the stack of layers 209. Gates 210A and 210C may be insulative gates, while gate 210B may be an active gate. Although non-limiting, active gate 210B may include a gate material 220 and a capping material 221, e.g., nitride, over the gate material 220. The insulative gates 210A and 210C may include a filler material 252, e.g., nitride. In some embodiments, each of the gates 210A-210C may include a stopping layer 222. For example, the stopping layer 222 may be a high-k layer, wherein a subsequent ion implantation condition may be slightly tuned with the additional high-k layer on the SOI layer 206. The high-k stopping layer 222 may act as an etch stop during removal of the gate material 220 and the capping material 221.

The device 250 may further include S/D regions 214A-214N formed along opposite sides of each of the gates 210A-210C. In some embodiments, the S/D regions 214 may be grown from an epitaxial material, such as a Si or SiGe material. The S/D regions 214 may also include a silicon capping material in some examples. In this embodiment, adjacent gates share a same S/D region. For example, insulative gate 210A and active gate 210B share S/D region 214A, while active gate 210B and insulative gate 210C share S/D region 214B. By sharing S/D regions, density of the device 250 is improved.

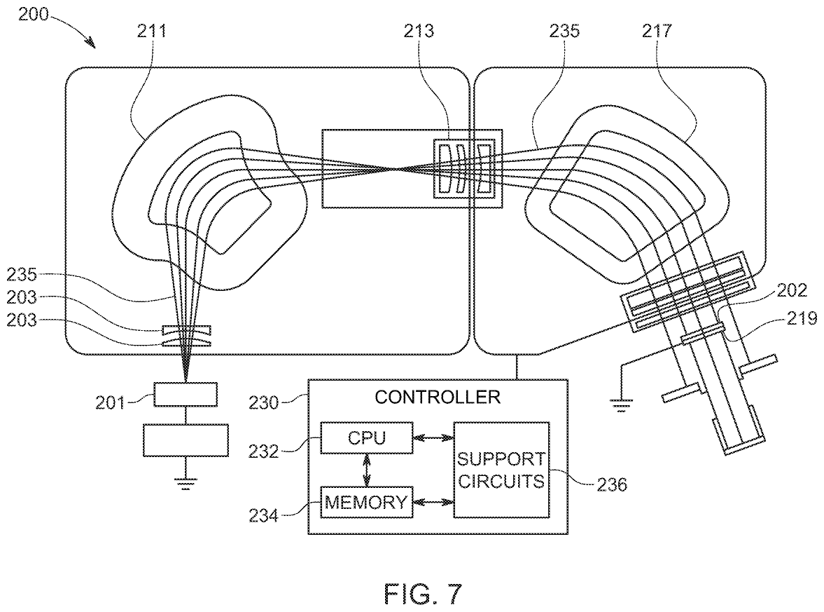

FIG. 7 illustrates a schematic diagram of a processing apparatus 200 useful to perform processes described herein. One example of a beam-line ion implantation processing apparatus is the Varian VIISTA® Trident, available from Applied Materials Inc., Santa Clara, CA. The processing apparatus 200 may include an ion source 201 for generating ions. For example, the ion source 201 may provide an ion implant, such as the oxygen ion implant 142 demonstrated in FIG. 4. The ion source 201 may also provide an ion etch.

The processing apparatus 200 may also include a series of beam-line components. Examples of beam-line components may include extraction electrodes 203, a magnetic mass analyzer 211, a plurality of lenses 213, and a beam parallelizer 217. The processing apparatus 200 may also include a platen 219 for supporting a substrate 202 to be processed. The substrate 202 may be the same as the substrate 102 described above. The substrate 202 may be moved in one or more dimensions (e.g., translate, rotate, tilt, etc.) by a component sometimes referred to as a “roplat” (not shown). It is also contemplated that the processing apparatus 200 may be configured to perform heated implantation processes to provide for improved control of implantation characteristics, such as the ion trajectory and implantation energy utilized to dope the substrate.

In operation, ions of the desired species, for example, dopant ions, are generated and extracted from the ion source 201. Thereafter, the extracted ions 235 travel in a beam-like state along the beam-line components and may be implanted in the substrate 202. Similar to a series of optical lenses that manipulate a light beam, the beam-line components manipulate the extracted ions 235 along the ion beam. In such a manner, the extracted ions 235 are manipulated by the beam-line components while the extracted ions 235 are directed toward the substrate 202. It is contemplated that the apparatus 200 may provide for improved mass selection to implant desired ions while reducing the probability of undesirable ions (impurities) being implanted in the substrate 202.

In some embodiments, the processing apparatus 200 can be controlled by a processor-based system controller such as controller 230. For example, the controller 230 may be configured to control beam-line components and processing parameters associated with beam-line ion implantation processes. The controller 230 may include a programmable central processing unit (CPU) 232 that is operable with a memory 234 and a mass storage device, an input control unit, and a display unit (not shown), such as power supplies, clocks, cache, input/output (I/O) circuits, and the like, coupled to the various components of the processing apparatus 200 to facilitate control of the substrate processing. The controller 230 also includes hardware for monitoring substrate processing through sensors in the processing apparatus 200, including sensors monitoring the substrate position and sensors configured to receive feedback from and control a heating apparatus coupled to the processing apparatus 200. Other sensors that measure system parameters such as substrate temperature and the like, may also provide information to the controller 230.

To facilitate control of the processing apparatus 200 described above, the CPU 232 may be one of any form of general-purpose computer processor that can be used in an industrial setting, such as a programmable logic controller (PLC), for controlling various chambers and sub-processors. The memory 234 is coupled to the CPU 232 and the memory 234 is non-transitory and may be one or more of readily available memory such as random access memory (RAM), read only memory (ROM), floppy disk drive, hard disk, or any other form of digital storage, local or remote. Support circuits 236 may be coupled to the CPU 232 for supporting the processor in a conventional manner. Implantation and other processes are generally stored in the memory 234, typically as a software routine. The software routine may also be stored and/or executed by a second CPU (not shown) that is remotely located from the hardware being controlled by the CPU 232.

The memory 234 is in the form of computer-readable storage media that contains instructions, that when executed by the CPU 232, facilitates the operation of the apparatus 200. The instructions in the memory 234 are in the form of a program product such as a program that implements the method of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

In various embodiments, design tools can be provided and configured to create the datasets used to pattern the semiconductor layers of the device 100, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading the Detailed Description, the various features and functionality described herein may be implemented in any given application and can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a plurality of gates in a stack of layers, wherein each gate of the plurality of gates comprises a sidewall spacer;
forming a mask over the stack of layers, wherein an opening through the mask exposes a dummy gate of the plurality of gates;
removing a gate material of the dummy gate to form a recess, wherein the recess exposes a silicon-on-insulator (SOI) layer of the stack of layers;
implanting oxygen ions into the recess; and
annealing the SOI layer within the recess to form an isolation area.

2. The method of claim 1, further comprising forming a fill material within the recess.

3. The method of claim 2, wherein the fill material is formed atop the isolation area.

4. The method of claim 1, wherein the isolation area is formed within the SOI layer.

5. The method of claim 1, wherein the gate material is etched selective to the sidewall spacer of the dummy gate.

6. The method of claim 1, wherein the oxygen ions are implanted at a temperature below 400° C.

7. The method of claim 1, wherein the oxygen ions are implanted at a temperature below 40° C.

8. The method of claim 1, further comprising forming the stack of layers by:
forming a buried oxide layer over a silicon substrate, wherein the SOI layer is formed over the buried oxide layer; and
forming a silicon oxide layer over the SOI layer.

9. A method of forming an isolation area in a silicon-on-insulator (SOI) device, the method comprising:
forming a plurality of gates in a stack of layers, wherein each gate of the plurality of gates comprises a sidewall spacer along a gate material;
forming a mask over the stack of layers, wherein an opening through the mask exposes a dummy gate of the plurality of gates;
etching the gate material of the dummy gate to form a recess, wherein the recess exposes a SOI layer of the stack of layers;
implanting oxygen ions into a bottom surface of the recess; and
annealing the bottom surface of the recess to form the isolation area in the SOI layer.

10. The method of claim 9, further comprising forming a fill material within the recess, wherein the fill material is formed atop the isolation area.

11. The method of claim 9, wherein the gate material of the dummy gate is removed selective to the sidewall spacer of the dummy gate.

12. The method of claim 9, wherein the oxygen ions are implanted at a temperature below 400° C.

13. The method of claim 9, further comprising forming the stack of layers by:
forming a buried oxide layer over a silicon substrate, wherein the SOI layer is formed over the buried oxide layer; and
forming a silicon oxide layer over the SOI layer.

14. The method of claim 9, wherein the gate material of the dummy gate is etched through the opening of the mask, and wherein no sacrificial spacer is present along a sidewall of the opening of the mask during the etching.

15. A method of forming a fully depleted silicon-on-insulator (FDSOI) device having a diffusion break, the method comprising:
forming a plurality of gates in a stack of layers, wherein each gate of the plurality of gates comprises a sidewall spacer along a gate material; and
forming a mask over the stack of layers, wherein an opening through the mask exposes a dummy gate of the plurality of gates;
forming the diffusion break by:
etching the gate material of the dummy gate to form a recess, wherein the recess exposes a SOI layer of the stack of layers;
implanting oxygen ions into a bottom surface of the recess to form an isolation area in the SOI layer; and
forming a fill material within the recess, wherein the fill material is formed atop the isolation area.

16. The method of claim 15, wherein the isolation area is further formed by annealing the bottom surface of the recess.

17. The method of claim 15, wherein the gate material of the dummy gate is etched selective to the sidewall spacer of the dummy gate.

18. The method of claim 15, wherein the oxygen ions are implanted at a temperature below 400° C.

19. The method of claim 15, further comprising forming the stack of layers by:
forming a buried oxide layer over a silicon substrate, wherein the SOI layer is formed over the buried oxide layer; and
forming a silicon oxide layer over the SOI layer.

20. The method of claim 15, wherein the gate material of the dummy gate is etched through exposed sidewalls of the opening of the mask.
